(19) United States
(12) Patent Application Publication
(10) Pub. No.: US 2001/0001413 A1
(43) Pub. Date: May 24, 2001

(54) METHOD AND APPARATUS FOR INCREASING WAFER THROUGHPUT BETWEEN CLEANINGS IN SEMICONDUCTOR PROCESSING REACTORS

(75) Inventors: STEPHEN P. DEORNELLAS, SANTA ROSA, CA (US); ALFRED COFER, PETALUMA, CA (US)

Correspondence Address: SHELDON R MEYER, FLIESLER DUBB MEYER & LOVEJOY, FOUR EMBARCADERO CENTER, SUITE 400, SAN FRANCISCO, CA, 941114156

(73) Assignee: Stephen P. DeOrnellas

(21) Appl. No.: 09/086,105

(22) Filed: May 28, 1998

(51) Int. Cl. H01L 21/00

(52) U.S. Cl. 156/345; 118/715

(57) ABSTRACT

A method and apparatus for increasing wafer throughput between cleanings in a semiconductor processing reactor 20 includes a mechanism 58 for exchanging any one of or combination of an electrode 32, a dispersion head 42, and related chamber walls 22 and insulation and/or other collecting surfaces or elements with replacement components without having to open the reaction chamber 24 to atmospheric pressure and thus, while maintaining the reaction chamber 24 at about the operating pressure or vacuum.

### FIELD OF THE INVENTION

The present invention is directed to semiconductor wafer processing equipment.

### BACKGROUND OF THE INVENTION

One of the major operational costs relating to semiconductor wafer processing equipment in a fabrication plant is the down time for cleaning of the tool. This down time is sometime measured by the number of wafers actually processed between reactor cleanings. Principally, a cleaning is required so that materials deposited on, for example, a top electrode, a gas dispersion head, and associated insulation and walls and other surfaces, can be removed prior to the commencement of additional processing operations. Appropriate cleaning is required so that the processed wafers will not be contaminated with particulate and other unwanted materials, resulting from such deposits, which could damage the wafer or circuits being fabricated. Generally, when it is determined that a tool must be cleaned, the tool or reactor down time is on the order of six to twelve hours.

With the introduction of the new 300 mm or 12 inch wafers and semiconductor tools capable of handling such wafers, it can be understood that during, for example, the etching process, several times the amount of material can be etched from the film on the wafer in comparison to the amount removed by a 200 mm or 8 inch wafer processing tool. That being the case, even more material can be deposited on the top electrode, the shower or dispersion head, and associated insulation and walls and other surfaces, and at a much higher rate. Potentially therefore, the mean number of wafers between cleanings could be drastically reduced, counteracting the potentially greater productivity from use of the 300 mm wafer processing tools.

Accordingly, there is a need to provide semiconductor processing tools which have an increased or enhanced mean number of wafers between cleanings.

### SUMMARY OF THE INVENTION

The present invention is directed to overcome the disadvantages of the prior art.

The present invention provides for a new paradigm in tool reactor design which can increase the wafer throughput and thus, increase the mean number of wafers processed between cleanings.

Accordingly, the present invention provides for a method and apparatus for increasing wafer throughput by providing for the exchange of, for example, a main electrode dispersion head, wall, insulation or other collecting surface of the tool or reactor without substantial loss of pressure or vacuum to the tool or reactor. With such an arrangement, it is an object to reduce the down time to an upper limit of less than about two hours, which is a reasonable period of time for efficient fabrication plant operation.

Accordingly, the present invention includes a semiconductor wafer processing tool comprising a reactor chamber and at least one of a first electrode dispersion head, wall, insulation and/or other collecting surface (all of, or any one of which can be referenced hereafter as a collecting surface), which is removably and operably positioned inside of said reactor chamber. The processing tool includes a device which holds a wafer in the chamber and an electrode chamber located outside the reactor chamber. The processing tool further includes a second electrode, dispersion head, wall, insulation and/or other collecting surface (again all, or any one of which can be referenced hereafter as a collecting surface), which is removably positioned inside of the electrode chamber and a communication mechanism that communicates said reactor chamber with said electrode chamber. The processing tool further includes a transfer mechanism that can move the first electrode or other first collecting surface from said reactor chamber through said communication mechanism to said electrode chamber. The transfer mechanism can also move said second electrode or other second collecting surface from the electrode chamber through the communication mechanism to an operable position inside of said reactor chamber. Thus, the transfer mechanism can exchange the second electrode or other collecting surface for the first electrode or other collecting surface.

The invention also includes a removable collecting surface which causes and protects a permanent and/or removable electrode.

The invention also includes a semiconductor wafer processing tool which comprises a reactor chamber including a main housing and a first electrode housing. A first electrode or other collecting surface is positioned in the first electrode housing. The process tool includes a device which is adapted to hold the wafer, which device is located in said main housing. The processing tool includes a second electrode housing located outside of said reactor chamber, and a second electrode or other collecting surface positioned in the second electrode housing. The tool has the first electrode housing associated with the second electrode housing so that with the movement of the first and second electrode housings, said second electrode can replace the first electrode or other collecting surface in said reactor chamber.

The invention further includes a method for increasing the wafer throughput between cleanings in semiconductor processing reactors or tools by providing for the transportation of a first electrode or other collecting surface out of a reactor and a second electrode or other collecting surface into a reactor while maintaining the reactor at about the appropriate pressure or vacuum in order to increase the mean number of wafers between cleanings.

Accordingly, it is an object of the present invention to increase the wafer throughput between cleanings in a semiconductor processing reactor.

It is another object of the present invention that etch reactors can effectively utilize the inventive aspects.

As a further object, the present invention provides for a reactor wherein a first electrode or other collecting surface which over time has been coated with materials related to the processing of wafers, can be switched with a clean electrode or other collecting surface in a manner that minimize downtime.

It is a further object of the present invention to provide for a method and apparatus for replacing a contaminated electrode or other collecting surface with a clean electrode or other collecting surface while substantially maintaining the pressure or vacuum levels in the reactor in order to minimize down time.

Thus it is an object of the invention to provide a reactor which can allow collecting surfaces to be exchanged without opening the reactor to atmospheric conditions, and thereby contaminating the reactor with moisture, gases, particles, and/or other materials.

Further objects, aspects and advantages of the invention can be obtained from review of the description, claims, and the figures.

### BRIEF DESCRIPTION OF THE FIGURES

FIG. 1 is a side schematical representation of a first embodiment of the invention.

FIG. 2 is a side schematical representation of a second embodiment of the invention.

FIG. 3 is a side schematical representation of a third embodiment of the invention.

FIG. 4 is a top schematical representation of the embodiment of FIG. 3.

FIG. 4a is a top schematic representation of another embodiment of the invention.

FIG. 5 is a top schematical representation of yet another embodiment of the invention.

FIG. 6 is a view through section 6-6 of FIG. 5.

FIG. 7 is a top schematical representation of a fourth embodiment of the invention.

FIG. 8 is a side schematical representation of the embodiment of FIG. 7.

### DETAILED DESCRIPTION OF THE PREFERRED EMBODIMENT

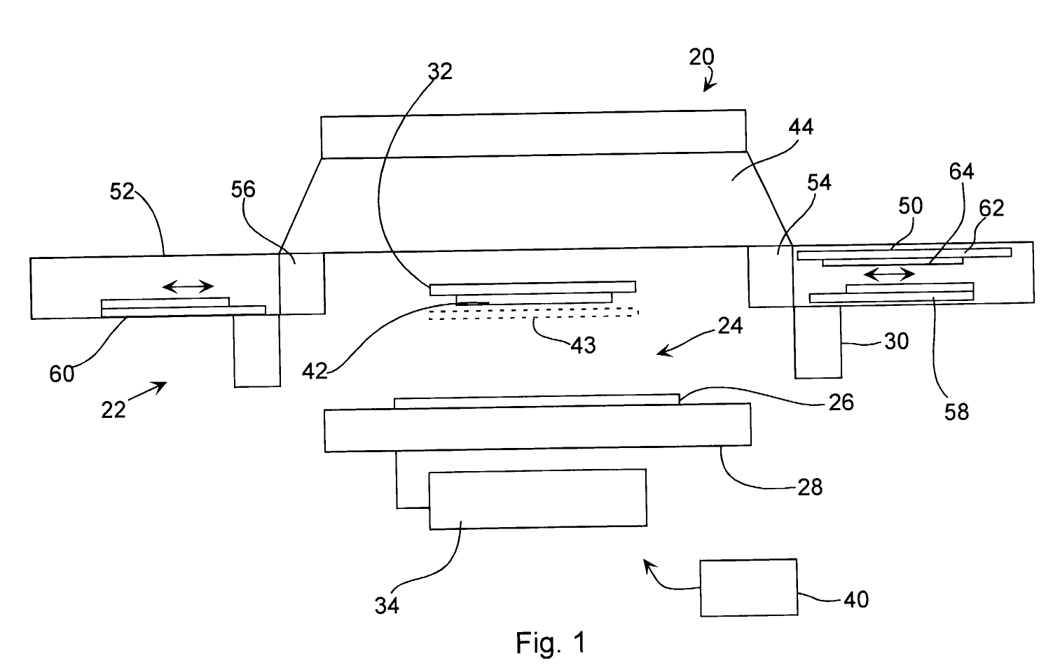

A side schematical representation of a first embodiment of the invention is shown in FIG. 1. The schematical representation is that of an etch reactor. It is to be understood, however, that other types of reactors including but not limited to other etch reactors can be used and be within the scope and spirit of the invention.

The etch reactor of FIG. 1 is identified by the number 20 and is configurated, as by way of this example only, a multi-frequency reactor. The etching apparatus 20 includes a housing 22 and an etching chamber 24. A wafer 26 is positioned on a bottom electrode 28. The chamber 24 further includes side peripheral electrode 30 and an upper electrode 32. In a preferred embodiment, the side peripheral electrode 30 can be grounded or allowed to establish a floating potential as a result of the plasma developed in the chamber 24. The upper electrode 32 is generally grounded, but can also be allowed to reach a floating potential, or in other configurations be communicated with a power source. In typical operation, both the side peripheral electrode 30 and the upper electrode 32 are grounded as shown in FIG. 1. However, again both of these electrodes can be allowed to have a floating potential or in other configurations can be communicated with a power source.

Preferably two A.C. power supplies 34, are connected to the bottom electrode 28 through a appropriate circuitry which includes matching networks and a combiner. Further a controller 40 controls the sequencing of the first and second AC power supplies 34. Typically, the first power supply operated in the kilohertz range and is optimally provided at about 450 KHz, and typically in the range of less than about 4 MHz. The second power supply operates in the megahertz range, and typically operates at about 13.56 MHz, although other frequencies above about 1 MHz and also multiples of 13.56 MHZ can be used with the present invention. The first power supply is powered at 200 watts and the second power supply is powered at 500 watts for this example. Further, it is understood that ion energy increases towards the kilohertz range while ion density increases towards the megahertz range.

A gas dispersion head 42 is located below the electrode 32. It is to be understood that the electrode and dispersion head can be two separate units or one integral unit. By way of a further example only, the gas dispersion head can include a ring with dispersion ports, which ring is positioned around the upper electrode.

Additionally, reactor 20 includes first and second external electrode (and/or other collection surface) housings 50 and 52. Housings 50 and 52 are connected to the reactor chamber 24 through load locks 54, 56 respectively. In this preferred embodiment, the first and second electrode housings include robotic arms 58, 60 respectively. Positioned in the first electrode housing 50 is a top electrode replacements 62 along with a dispersion head replacement 64. Other collection surface replacements can be stored in the housings and used to replace contaminated collection surfaces of the reactor.

The operation of the reactor 20, for purposes of replacing the electrode 32 and dispersion head 42 with the electrode 62 and dispersion head 64 or other collection surface is as follows: After a number of wafers are processed in the reactor 20, the electrode 32, and dispersion head 42, will have been coated with process materials to a level which would not provide for continued satisfactory wafer throughput or cleanliness. Accordingly, wafer processing is ceased in the reactor 20. At that point, and without bringing the reactor chamber 24 to atmospheric pressure by opening said chamber to the atmosphere, load lock 56 can be opened and robotic arm 60 can be inserted into chamber 24 in order to engage and detach electrode 32 and dispersion head 42 or other collecting surface from appropriate positioning and retaining mechanisms in chamber 24. The robotic arm 60 can then remove the electrode 32 and the dispersion head 42 or other collecting surface through load lock 56 into electrode housing 52. At this point, and after load lock 56 is again closed, the electrode 32 and head 42 or other collecting surface can be removed from electrode housing 32 for appropriate cleanings. Once the electrode 32 and dispersion head 42 or other collecting surface are removed, load lock 54 can be opened and electrode 62 with dispersion head 64 or other replacement collecting surface can be inserted into the chamber 24 using the robotic arm 58. The robotic arm 58 positions the electrode 62 and the dispersion head 64 or other collecting surface appropriately in chamber 24 so that positioning and retaining mechanisms can engage the electrode 62 and the dispersion head 64 or other collecting surface. Once this has been completed, the load lock 54 is closed. Thus, it can be seen that the above operation can be completed efficiently and rapidly, without bringing the reactor chamber to atmospheric pressure and thus, by maintaining the reactor chamber at about the desired pressure (atmospheric or above) and/or vacuum throughout the exchange process.

It is also to be understood that the electrode can be protected by a shield or other collecting surface 43 which can be replaced in the above manner with a replacement shield stored in housing 50. The shield would be removably fastened to the reactor and/or removably positioned between the electrode and/or dispersion head and the chuck which holds a wafer.

Such a collecting surface 43 is depicted in phantom in FIG. 1. Surface 43 can be comprised of a shield with ports which allow the plasma to penetrate into the chamber toward the wafer and the chuck. Collecting surface 43 can be comprised of a conductor or an insulator. As a conducting collecting surface 43 can comprise aluminum, anodized aluminum, carbon, and a variety of carbon based compounds to name a few. As an insulator surface 43 can comprise of quartz, silicon, Teflon, Delrin, Nylon, polyamide and a variety of other organic compounds.

In such a situation it is the shield or collecting surface 43 that is replaced and not the electrode and/or gas dispersion head. In general, it is preferably for a shield to be replaced and not the entire assembly of the electrode and/or the gas dispersion head. If only the shield needs to be replaced, the operation is cheaper and faster. If the input process gas dispersion head is a part of the shield, then it is replaced also.

Thus, it is to be understood that at least the following combinations are possible and be within the spirit and scope of the invention:

1. The electrode and dispersion head are separate units and one or both of these can be replaced.

2. The electrode and dispersion head are one unit (i.e., the electrode has gas dispersion ports and the whole unit can be replaced.

3. The electrode is a first unit and the dispersion head and shield are a second unit, and the second unit can be replaced.

4. The electrode and dispersion head are each separate units protected by a replaceable shield.

5. The electrode and dispersion head are one unit protected by a replaceable shield.

6. The electrode, dispersion head, and shield are each separate units and any one of these or any combination of these can be replaced.

Further, the collecting surface would ideally have a coefficient of expansion which is comparable to an electrode, dispersion head, or other element it would shield for deposits.

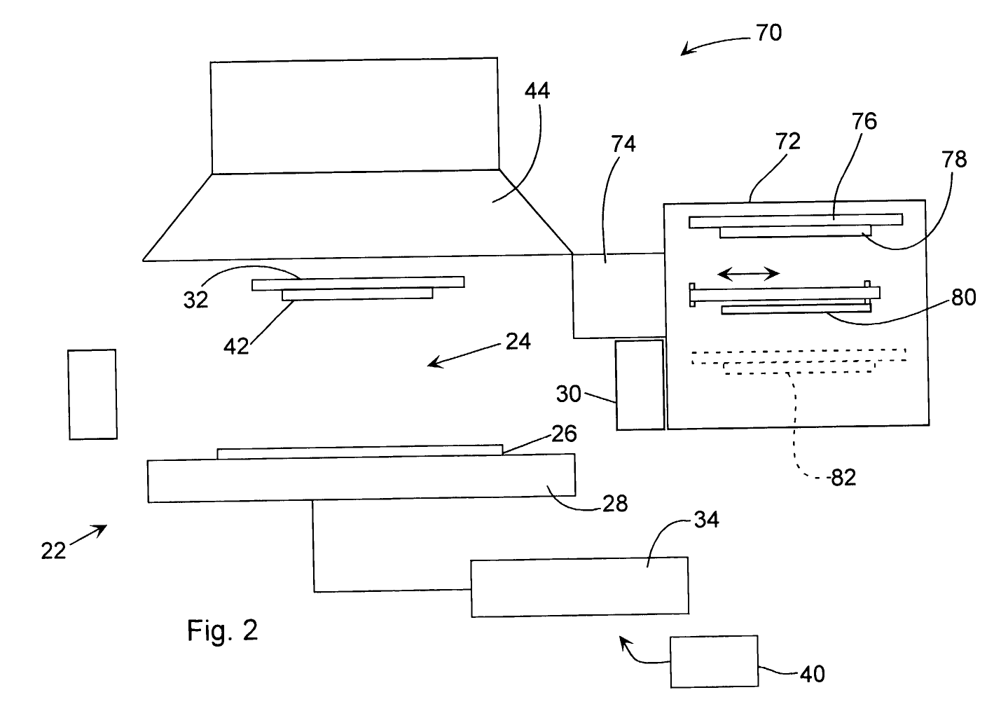

FIG. 2 depicts an embodiment of a reactor 70 of the invention. Elements of reactor 70 which are similar to elements of reactor 20 in FIG. 1 are similarly numbered. In addition, reactor 70 includes electrode housing 72 which is connected to the chamber 24 by a load lock 74. Inside of electrode housing 72 is a first top electrode replacement 76 with a dispersion head replacement 78 or other collecting surface. Also enclosed in the electrode housing 72 is a robotic arm 80.

The operation of the embodiment of the reactor 70 in FIG. 2 is as follows: Once it is determined that the electrode 32 and the dispersion head 42 other collecting surfaces need to be cleaned, and the process for the last wafer has terminated, without exposing the chamber 24 to atmospheric pressure, load lock 74 is opened. Robotic arm 80 is inserted through load lock 74 into engagement with electrode 32 and the dispersion head 42. Robotic arm 80 then removes electrode and dispersion heads or other collecting surfaces and positions them in the housing 72 at position 82. After this occurs, the robotic arm 80 then transports the replacement electrode 76 and replacement dispersion head 78 or other replacement collecting surfaces from the housing 72 into position in the chamber 24. After this has occurred, the load lock is closed.

It is to be understood that although all the above embodiments are described with respect to replacement of the top electrode and the dispersion head, that other embodiment can be carried out equally well by replacing other electrodes and/or collecting elements or surfaces. Still further, the invention can be carried out by replacement of any combination of electrodes, dispersion head, and top surface portions of the reactor associated with and surrounding the electrode and dispersion head and other collecting surface and elements.

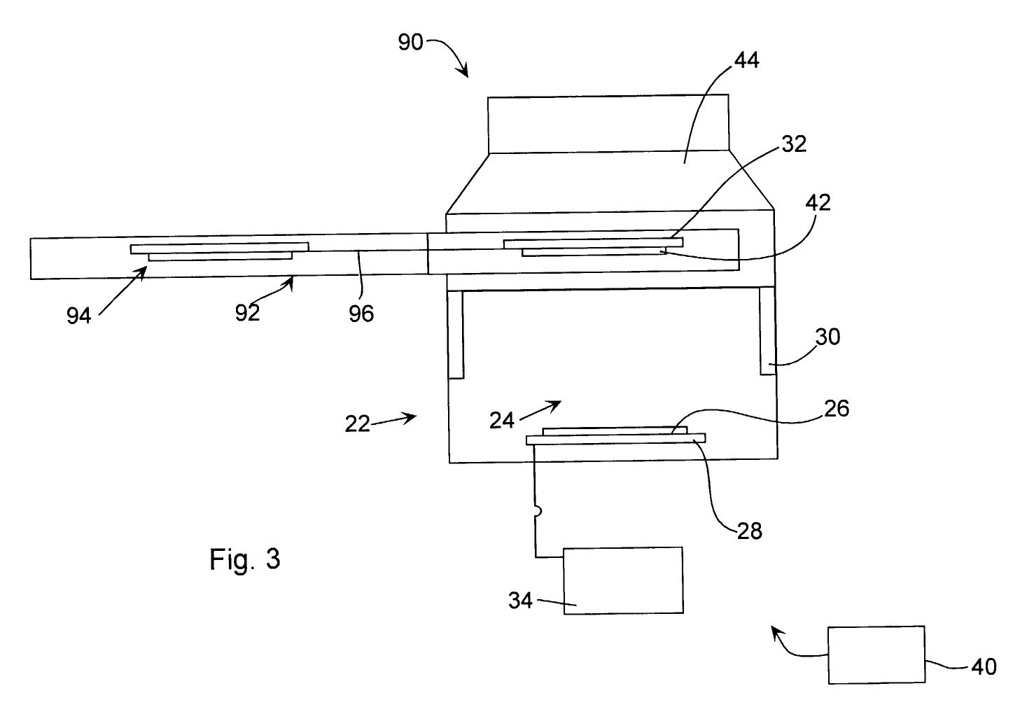

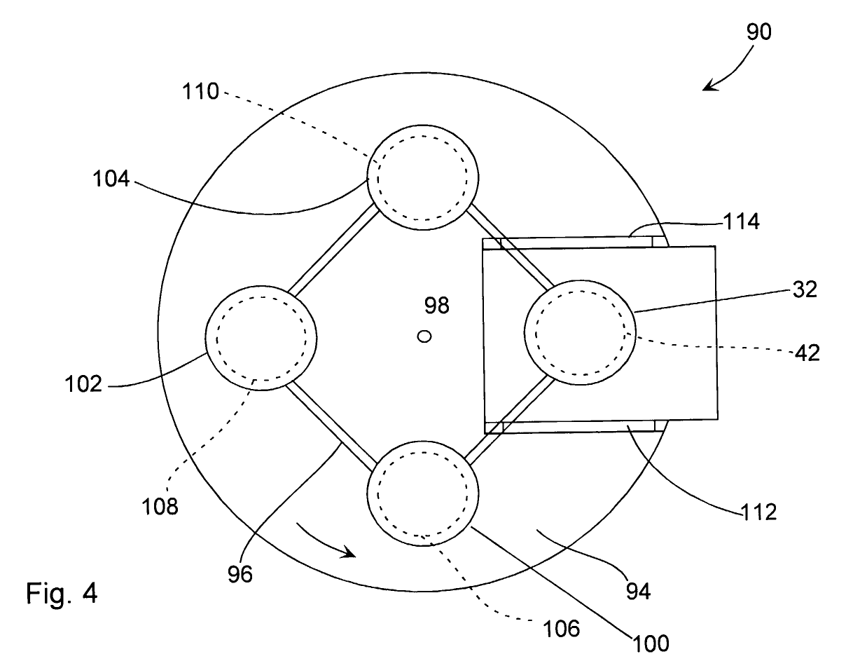

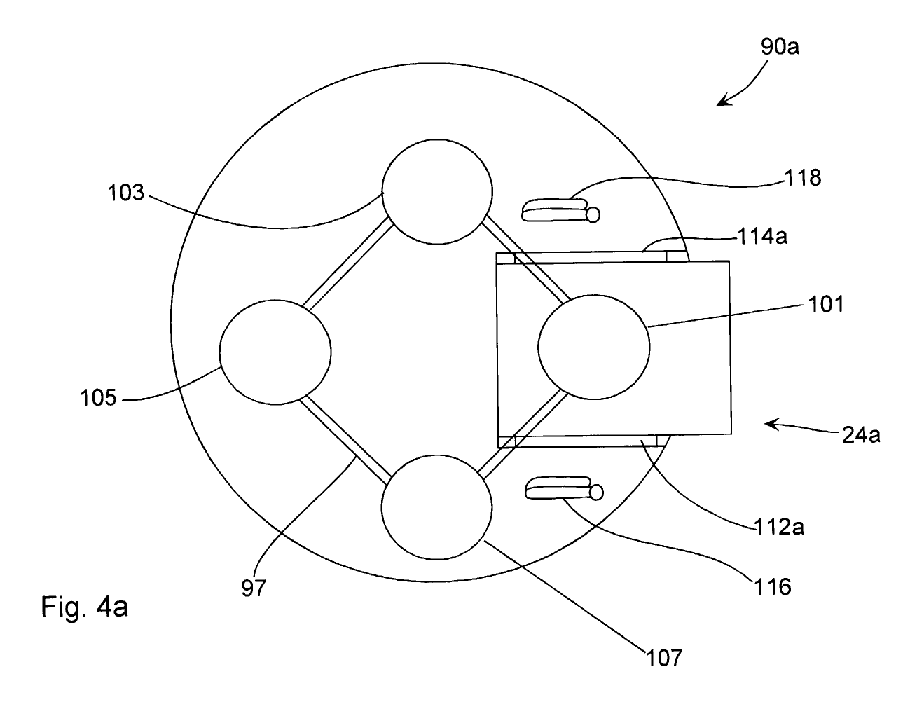

Another embodiment of the present invention is depicted in FIGS. 3 and 4, and includes reactor 90. Elements of reactor 90 which are similar to those in FIGS. 1 and 2 are numbered similarly.

Reactor 90 additionally includes a carousel housing 92 which houses a carousal mechanism 94. Carousel mechanism 94 includes a carriage 96 which is pivotable about pivot point 98 and can define the top surfaces of a reactor. Mounted on carriage 96 are the electrode 32 and the dispersion head 42 and/or collecting surfaces. In addition, the second, third, and fourth electrodes 100, 102, and 104, and second, third and fourth dispersion heads 106, 108, and 110 are mounted on the carriage 96. These electrode and dispersion head pairs also define top surfaces of the reactor and are preferably equally spaced and mounted in quadrants of the carriage 96 in this particular embodiment.

Of course, more than these pairs can be mounted on the carriage 96 with a plurality of positions and be within the spirit and scope of the inventions. The reactor 90 further includes load lock doors 112 and 114.

In operation, once the top surfaces of the reactor, including but not necessarily limited to, the electrode 32 and the dispersion head 42 are coated with process materials, and the last wafer has been removed from the reactor, without opening the reactor chamber 24 to atmospheric pressure, both load lock doors 112 and 114 are opened. This allows the carriage 96 to pivot about pivot point 98 in a counterclockwise direction in order to move electrode 100 and dispersion head 106 into position in the reactor chamber 24 and simultaneously remove coated top surfaces including the electrode 32 and dispersion head 42. Once this has occurred, the load lock doors 112, 114 again seal the reaction chamber 24 so that additional wafer processing can commence. Alternatively, the carousel can comprise a shield which rotate past a fixed electrode and dispersion head. Once a portion of the shield has deposits built-up thereon, the carousel rotates so that a new clean shield portion from the carousel protects the stationary electrode and dispersion head. With respect to the above embodiment, it is to be appreciated that the load lock doors can be designed in such a manner so that they can seal about the carriage mechanism.

Alternatively as depicted in FIG. 4a, a carriage mechanism 97 can be stationary and can include a track mechanism that the shields, electrode and/or dispersion heads are transported upon. In this embodiment only, shields are transported into a protecting relationship with a fixed electrode and gas dispersion head in the reactor chamber. These shields are designated 101, 103, 105, and 107. The track mechanism 97 can include, for example, trucks or wheel mechanisms upon which the shields are mounted in order to allow the shields to ride over the carriage mechanism. In FIG. 4a, elements that are similarities to the elements in FIG. 4 are given an “a” designation. In the area of the load lock doors 112a, 114a, the carriage mechanism can end, and robotic arm 118 can then be used to remove the coated shield from the reaction chamber 24a, and place these on the track of the carriage mechanism. Then robotic arm 116 can engage a new shield or other collecting surface from the carriage mechanism and insert this into chamber 24a in the reactor 90a.

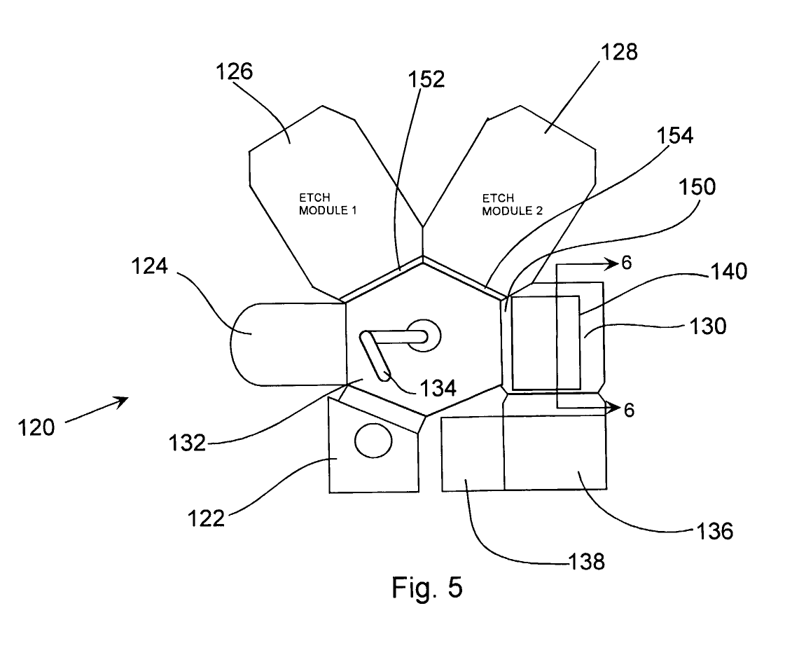

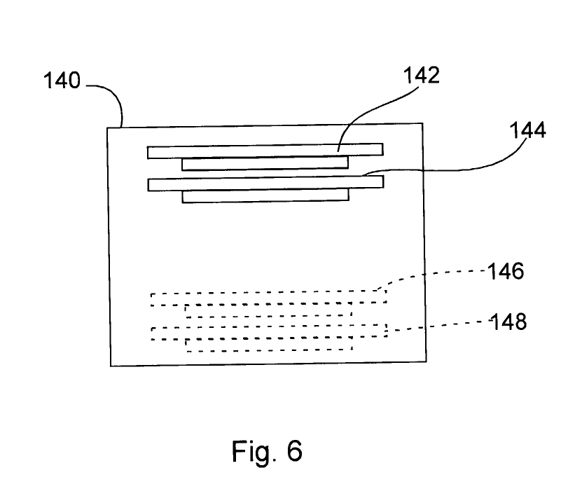

Another embodiment of the invention is depicted in FIGS. 5 and 6. FIG. 5 depicts a cluster tool having two etch modules. FIG. 5 illustrates a preferred embodiment of a system 120 in accordance with the present invention. The system 120 includes a vacuum load lock chamber 122, an alignment module 124, two etch modules 126, and 128, and a strip module 130, all of which are connected to a central vacuum chamber 132 through a closeable opening and are operated by a computer process control system (not shown). Load lock chamber 122 houses an internal cassette elevator for holding a wafer cassette (entry cassette). Vacuum chamber 132 has a robotic wafer handling system 134 for transferring wafers from one chamber or module to another. Strip module 130 is connected to an atmospheric robotic wafer handling system 136 through a closeable opening, which system 136 in turn is connected to rinse module 138. The second robotic wafer handling system 136 transfers wafers between strip module 130 and rinse module 138. The atmospheric robotic wafer handling system services the atmospheric cassette module which holds wafers after the completion of processing.

Above the strip module 130 is a replacement electrode housing 140 which is shown in FIG. 6. Housing 140 has sufficient space to house first and second replacement electrode and dispersion head pairs 142, 144 or preferably replacement collecting surfaces or shields or elements which can protect permanently positioned electrodes and/or dispersion heads. Additionally, there is sufficient space to house original electrode and dispersion head pairs 146, 148 or collecting surfaces or shields, which were initially mounted in the etch modules 126, 128. This embodiment further includes load lock 150 which allows access to electrode housing 140 and load locks 152, 154 which allows access to first and second etch modules 126, 128.

In operation, once wafer processing has ceased, robotic arm 134 is used to remove the electrode and dispersion head pair or other collecting surface or element from the first etch module 126 and place it in the electrode housing 140 in the position of pair 148. Then, robotic arm 134 removes the electrode and dispersion head pair 144 from the housing 140 and places it into the etch module 126. Similarly, the electrode from the second etch module 128 is removed and positioned in the position 146 down in FIG. 6, and replacement electrode and dispersion head pair 142 is moved from the housing 140 by the robotic arm 134 and placed in the second etch module 128. It is to be understood that although it is contemplated that in this and other embodiments, that electrodes and dispersion pairs can be replaced as a unit, in other embodiments either an electrode or a dispersion head can be replaced separately as desired.

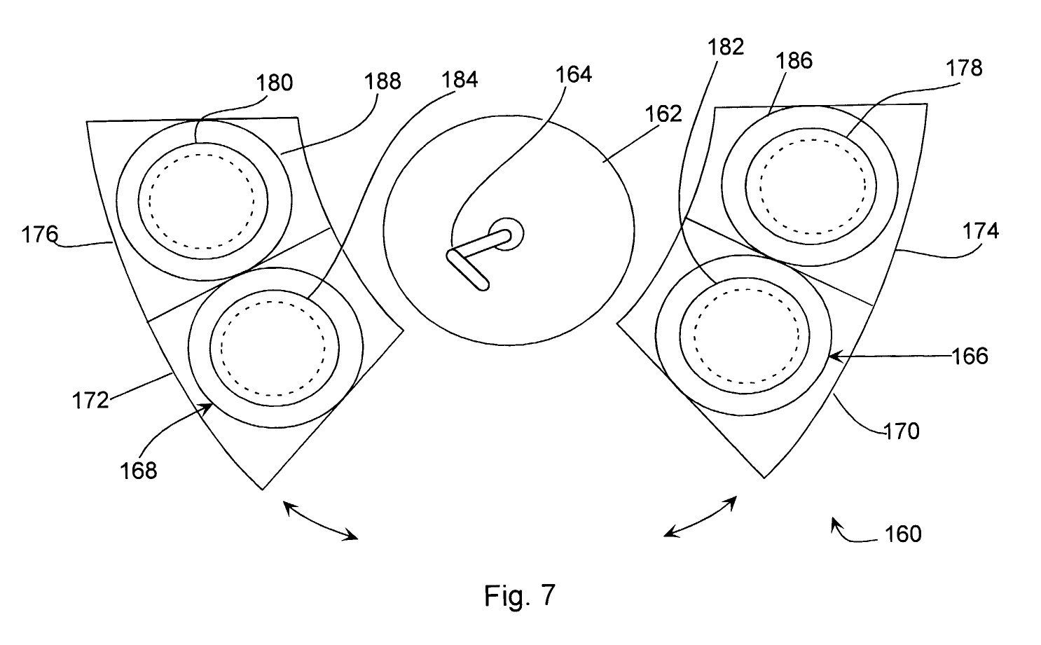

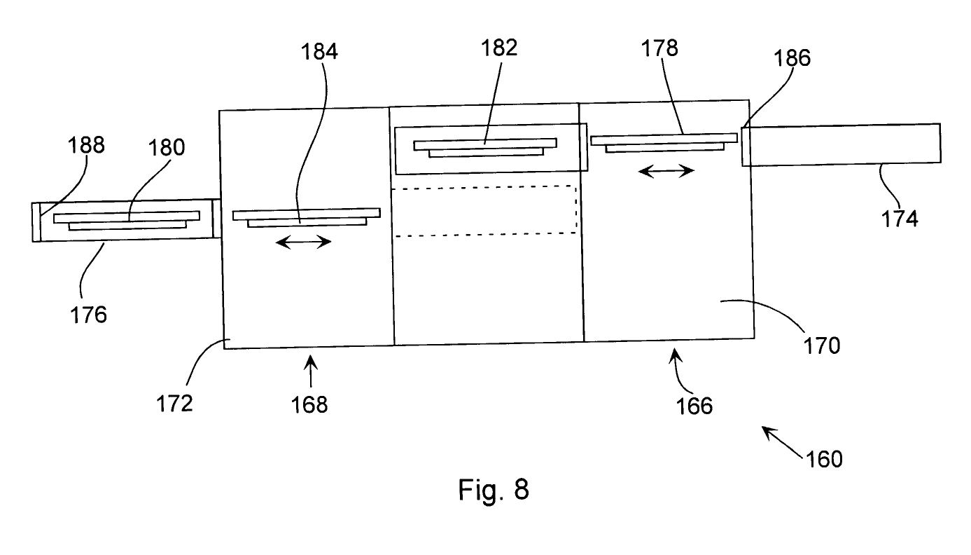

Still another embodiment of the invention is shown in FIGS. 7 and 8 and includes tool 160. Tool 160 includes a central vacuum chamber 162 which includes robotic transfer mechanism 164. Tool 160 includes first and second reaction chambers 166, 168, which are enclosed in main housings 170, 172. This embodiment also includes external electrode housings 174 and 176. External electrode housings 174 and 176 house replacement electrode and dispersion head pairs 178, 180, or other collecting surfaces or elements which are used to replace the original electrode and dispersion head pairs 182, 184 or other original collecting surfaces or elements.

The external electrode housings 174, 176 further include internal housings 186, 188, which move in and out of the external housings 174, 176, with the electrode and dispersion head pairs. These internal housings 186, 188 are essentially, in this particular embodiment, vertical walls, which mate the vertical walls of the reaction chambers 166, 168. Thus, in order to exchange the original electrode and dispersion head pair 182 for the replacement pair 178 as is shown in FIG. 7, both the replacement pair 178 and also the vertical side walls 186 are shifted from the external housing 174 into the reactor chamber 166 with similar walls and the electrode and dispersion head pair 182 shifted out of the reactor chamber 166. Once this has occurred, appropriate seals are used to engage the inner housing 186 in order to seal the chamber so that the wafer processing can commence. Thus in this embodiment, it is contemplated that the entire top surface of the reactor is exchanged with a clean top surface.

As can be seen in FIG. 8, the original electrode and dispersion head 184 has been replaced by the replacement pair 178. Also, it is evident that the original electrode and dispersion head pair 184 installed in the reactor chamber 172 can be replaced by the replacement electrode and dispersion head pair 182. Further as can be seen in FIG. 8, the elevation of electrode and head pair 180 is higher than the elevation of electrode and head pair 184 so that both can be exchanged at the same time without interfering with each other.

All the above operations can occur without venting the reaction chambers to atmosphere and thus the downtime is minimized in accordance with the invention.

### INDUSTRIAL APPLICABILITY

The above embodiments demonstrate the advantages of the invention. It includes the ability to reduce the downtime required to change one or more of an electrode, a dispersion head, and associated walls and insulation, or other collecting surface or element in any combination, once they have been coated with process materials. Such exchanges provide for an appropriate throughput of wafers while reducing imperfections.

Other features, aspects and objects of the invention can be obtained from a review of the figures and the claims.

It is to be understood that other embodiments of the invention can be developed and fall within the spirit and scope of the invention and claims.

We claim:

1. A semiconductor wafer processing tool comprising:
a reactor chamber;
a first collecting element which is removably and operably positioned inside of said reactor chamber;
a collecting element chamber located outside of said reactor chamber;
a second collecting element which is removably positioned inside of said collecting element chamber;
a communication mechanism that communicates said reactor chamber with said collecting element chamber; and
a transport mechanism that can move said first collecting element from said reactor chamber through said communication mechanism to said collecting element chamber and can also move said second collecting element from the collecting element chamber through said communication mechanism to operably position said second collecting element inside of said reactor chamber in order to exchange the first collecting element for the second electrode.

2. The tool of claim 1 wherein:
said communication mechanism includes a load lock which can allow the first collecting element and the second collecting element to be exchanged while maintaining the reactor chamber at a desired pressure or vacuum.

3. A semiconductor wafer processing tool comprising:
a reactor chamber including a main housing and a first collecting element housing;
a first collecting element positioned in said first collecting element housing;
a second collecting element housing located outside of said reactor chamber;
a second collecting element positioned in said second collecting element housing;
said first collecting element housing associated with said second collecting element housing so that through movement of said first and second collecting element housings, said second collecting element can replace said first collecting element in said reactor chamber.

4. The tool of claim 3 including:
a load lock which can allow the first collecting element and the second collecting element to be exchanged while maintaining the reactor chamber at a desired pressure or vacuum.

5. The tool of claim 3 wherein:
said second collecting element housing includes an inner housing that supports the second collecting element and an outer housing that contains the inner housing and the second collecting element; and
wherein said second collecting element and said inner housing is moved into engagement with the reactor chamber in order to replace the first collecting element with the second collecting element.

6. The tool of claim 5 wherein:
said reactor chamber has a reactor chamber wall; and
said inner housing of the second collecting element housing can form a part of said reactor chamber wall with the second collecting element operably positioned in said reactor chamber.

7. The tool of claim 3 including:
said first collecting element including a first electrode and said second collecting element including a second electrode;
a first process gas dispersion head associated with said first electrode;
a second process gas dispersion head associated with said second electrode; and
wherein said second process gas dispersion head replaces said first process gas dispersion head with the replacement of the first electrode with the second electrode.

8. The tool of claim 1 including:
said first collecting element including a first electrode and said second collecting element including a second electrode;
a first process gas dispersion head associated with said first electrode;
a second process gas dispersion head associated with said second electrode; and
wherein said second process gas dispersion head replaces said first process gas dispersion head with the replacement of the first electrode with the second electrode.

9. The tool of claim 1 including:
said first collecting element including a first electrode and said second collecting element including a second electrode;
said reactor chamber having a reactor chamber wall and wherein a first portion of said reactor chamber wall is associated with and movable with said first electrode; and
said second electrode has associated therewith a second portion of said reactor chamber wall which is substantially identical to said first portion of said reactor chamber wall so that with the exchange of said first electrode for said second electrode said first portion of said reactor chamber wall is exchanged for said second portion of said reactor chamber wall.

10. The tool of claim 1 wherein:
said transport mechanism includes a robotic arm.

11. The tool of claim 4 including:
another load lock associated with the first collecting element housing that allows the first collecting element to be removed from said first collecting element housing for cleaning without substantially effecting the operation of the reactor chamber.

12. The tool of claim 2 including:
another load lock associated with the collecting element chamber that allows the first collecting element to be removed from said collecting element chamber for cleaning without substantially effecting the operation of the reactor chamber.

13. A semiconductor wafer processing tool comprising:
a reactor chamber;
a first collecting element which is removably and operably positioned inside of said reactor chamber;
a first collecting element chamber located outside of said reactor chamber;
a second collecting element which is removably positioned inside of said first collecting element chamber;
a second collecting element chamber located outside of said reactor chamber;
a first communication mechanism that communicates said reactor chamber with said first collecting element chamber;
a second communication mechanism that communicates said reactor chamber with said second collecting element chamber;
a first transport mechanism that can move said first collecting element from said reactor chamber through said second communication mechanism to said second collecting element chamber; and
a second transport mechanism that can move said second collecting element from said first electrode chamber through said first communication mechanism into operable position in said reactor chamber in order to exchange the second collecting element for the first collecting element.

14. The tool of claim 13 wherein:
said first communication mechanism includes a first load lock which allows the second collecting element to be placed in the reactor chamber while maintaining the reactor chamber at one of a desired pressure and a desired vacuum; and
said second communication mechanism includes a second load lock which allows the first collecting element to be removed from the reactor chamber while maintaining the reactor chamber at one of a desired pressure and a desired vacuum.

15. A method for increasing the wafer throughput between cleanings in semiconductor processing reactors comprising the steps of:
first moving a first collecting element which has been coated with process materials from a reactor chamber to a collecting element housing without opening said reactor chamber to atmospheric pressure and environment contamination;
second moving a second collecting element from one of said collecting element housing and another collecting element housing, into operable position in said reactor chamber without opening said reactor chamber to atmospheric pressure and environment contamination.

16. The method of claim 15 wherein:
said first moving step includes moving said first collecting element through a load lock from said reactor chamber to said collecting element housing; and
said second moving step includes moving said second collecting element through one of said load lock and another load lock in order to move said second collecting element from one of said collecting element housing and said another collecting element housing to said reactor chamber.

17. A semiconductor wafer processing tool comprising:
a reactor chamber;
a first collecting element which is removably and operably positioned inside of said reactor chamber;
a collecting element carousel chamber located outside of said reactor chamber;
a communication mechanism which communicates said reactor chamber with said collecting element carousel chamber;
said collecting element carousel chamber housing a carousel mechanism on which is mounted one or more replacement collecting elements; and
said carousel mechanism capable of moving said one or more replacement collecting elements into said reactor chamber and moving said first collecting element out of said reactor chamber without exposing said reactor chamber to atmospheric pressure.

18. The tool of claim 17 wherein:
said carousel mechanism includes a track upon which one of said replacement collecting elements can be transported inside said electrode carousel chamber and a robotic arm which can move one of said replacement collecting elements from the collecting element carousel chamber to said reactor chamber.

19. The tool of claim 17 wherein:
said carousel mechanism includes a structure upon which at least one said replacement collecting element can be transported; and
said structure is pivotably mounted inside said collecting element carousel chamber in order to transport said replacement collecting element.

20. The tool of claim 1 wherein:
said communication mechanism includes a central chamber; and
said transportation mechanism is located in said central chamber through which said first and second collecting elements must pass in order to exchange the second collecting element for the first collecting element.

21. The tool of claim 1 wherein:
said collecting element can include at least one of an electrode, a dispersion head, a wall, and a top surface of a reactor.

22. The tool of claim 3 wherein:
said collecting element can include at least one of an electrode, a dispersion head, a wall, and a top surface of a reactor.

23. The tool of claim 13 wherein:
said collecting element can include at least one of an electrode, a dispersion head, a wall, and a top surface of a reactor.

24. The tool of claim 17 wherein:
said collecting element can include at least one of an electrode, a dispersion head, a wall, and a top surface of a reactor.

25. The tool of claim 1 wherein:
said collecting element can be one of a conductor and a insulator.

26. The tool of claim 3 wherein:
said collecting element can be one of a conductor and a insulator.

27. The tool of claim 13 wherein:
said collecting element can be one of a conductor and a insulator.

28. The tool of claim 17 wherein:
said collecting element can be one of a conductor and a insulator.

29. The tool of claim 1 wherein:
said collection element covers a fixed element of the tool and has a coefficient of expansion comparable to said fixed element.

30. The tool of claim 3 wherein:
said collecting element covers a fixed element of the tool and has a coefficient of expansion comparable to said fixed element.

31. The tool of claim 13 wherein:
said collecting element covers a fixed element of the tool and has a coefficient of expansion comparable to said fixed element.

32. The tool of claim 17 wherein:
said collecting element covers a fixed element of the tool and has a coefficient of expansion comparable to said fixed element.

33. A replacement unit for a semiconductor wafer processing tool with a reactor chamber defined by a reactor wall, said replacement unit comprising:
a selectively removable collecting surface that can collect process materials; and
a selectively removable portion of the reactor wall that is associated with said collecting surface such that said collecting surface and said portion of said reactor wall can be removed together.

34. The replacement unit of claim 33 wherein:
said collecting surface includes at least one of an electrode, and a dispersion head.
